(19) United States
(12) Patent Application Publication
(10) Pub. No.: US 2010/0078638 A1
(43) Pub. Date: Apr. 1, 2010

(54) IMAGE SENSOR AND METHOD FOR FABRICATING THE SAME

(76) Inventors: Han-Choon Lee, Songpa-gu (KR); Oh-Jin Jung, Bucheon-si (KR)

Correspondence Address: SHERR & VAUGHN, PLLC, 620 HERNDON PARKWAY, SUITE 320, HERNDON, VA, 20170, US

(21) Appl. No.: 12/568,813

(22) Filed: Sep. 29, 2009

(30) Foreign Application Priority Data
Oct. 1, 2008 (KR) 10-2008-0096404

(51) Int. Cl. H01L 31/0376; H01L 31/18

(52) U.S. Cl. 257/53; 438/96; 257/E31.061; 257/E31.047

(57) ABSTRACT

An image sensor and a method of fabricating an image sensor. An image sensor may include a readout circuitry arranged over a semiconductor substrate, an interlayer dielectric film provided with metal lines arranged over a semiconductor substrate, and/or a lower electrode arranged over a interlayer dielectric film such that a lower electrode may be connected to metal lines. An image sensor may include a first-type conductive layer pattern arranged over a lower electrode, an intrinsic layer arranged over a surface of a semiconductor substrate such that an intrinsic layer may substantially cover a first-type conductive layer pattern. An image sensor may include a second-type conductive layer arranged over an intrinsic layer. A method of fabricating an image sensor may include a patterned n-type amorphous silicon layer which may be treated with N₂O plasma. A method of fabricating an image sensor may include H₂ annealing.

The present application claims priority under 35 U.S.C. 119 to Korean Patent Application No. 10-2008-0096404 (filed on Oct. 1, 2008), which is hereby incorporated by reference in its entirety.

### BACKGROUND

Embodiments relate to electric devices and methods thereof. Some embodiments relate to an image sensor and a method of fabricating an image sensor.

Image sensors may be semiconductor devices and may convert optical images into electric signals. Image sensors may include charge coupled device (CCD) image sensors and/or complementary metal oxide silicon (CMOS) image sensors. CMOS image sensors may include photodiodes and/or MOS transistors in and/or over unit pixels which may detect electric signals in their respective unit pixels in a switching mode, thereby realizing an image. A CMOS image sensor may have a structure in which a photodiode portion, used to convert light signals into electric signals, and a transistor portion, used to handle electric signals, may be horizontally arranged. Horizontal CMOS image sensors may have a structure in which photodiodes and transistors are arranged horizontally adjacent to each other in and/or over a substrate. However, horizontal CMOS image sensors may require an additional region where photodiodes may be formed, which may relatively decreases a fill factor region and/or may relatively limit resolution.

Accordingly, there is a need for an image sensor and a method of fabricating the same which may include a vertical integration between a transistor circuit and a photodiode. There is a need for an image sensor and a method of fabricating the same which may substantially remove noise in a pixel and/or substantially prevent cross-talk. There is a need for an image sensor and a method of manufacturing the same which may maximize image properties, which may substantially remove defect-causing materials and/or address damage.

### SUMMARY

Embodiments relate to an image sensor and a method of fabricating an image sensor. According to embodiments, an image sensor and a method of manufacturing the same may provide vertical integration between a transistor circuit and a photodiode. In embodiments, an image sensor and a method of fabricating an image sensor may substantially remove noise in a pixel. In embodiments, an image sensor and a method of fabricating an image sensor may substantially prevent cross-talk. Image properties may be maximized in accordance with embodiments.

Embodiments relate to a method of fabricating an image sensor. According to embodiments, a method of fabricating an image sensor may include patterning an n-type amorphous silicon layer. In embodiments, a method of fabricating an image sensor may include treating an n-type amorphous silicon layer using N₂O plasma. In embodiments, a method of fabricating an image sensor may include treating using N₂O plasma to cure a patterned n-type amorphous silicon layer. In embodiments, defect-causing materials on and/or over an interface may be substantially removed.

Embodiments relate to a method of fabricating an image sensor. According to embodiments, a method of manufacturing an image sensor may include hydrogen annealing. In embodiments, hydrogen annealing may cure oxygen plasma damage present on and/or over an n-type amorphous silicon layer.

Embodiments relate to an image sensor. According to embodiments, an image sensor may include a readout circuitry arranged on and/or over a substrate, such as a semiconductor substrate. In embodiments, an image sensor may include an interlayer dielectric film which may be provided with metal lines, and/or which may be arranged on and/or over a semiconductor substrate. In embodiments, an image sensor may include a lower electrode arranged on and/or over an interlayer dielectric film. A lower electrode may be connected to metal lines in accordance with embodiments.

According to embodiments, an image sensor may include a first-type conductive layer pattern arranged on and/or over a lower electrode. In embodiments, an image sensor may include an intrinsic layer arranged on and/or over a surface of a semiconductor substrate, which may be the entire surface of a semiconductor substrate. In embodiments, an image sensor may include an intrinsic layer which may substantially cover a first-type conductive layer pattern. In embodiments, an image sensor may include a second-type conductive layer arranged on and/or over an intrinsic layer.

Embodiments relate to a method of fabricating an image sensor. According to embodiments, a method of manufacturing an image sensor may include forming a readout circuitry on and/or over a substrate, such as a semiconductor substrate. In embodiments, a method of manufacturing an image sensor may include forming an interlayer dielectric film provided with metal lines on and/or over a semiconductor substrate. In embodiments, a method of manufacturing an image sensor may include forming an upper dielectric film on and/or over a interlayer dielectric film. In embodiments, a method of manufacturing an image sensor may include forming a lower electrode connected to metal lines on and/or over an upper dielectric film.

According to embodiments, a method of manufacturing an image sensor may include forming a first-type conductive layer on and/or over a lower electrode and/or an upper dielectric film. In embodiments, a method of manufacturing an image sensor may include patterning a first-type conductive layer, which may form a first-type conductive layer pattern on and/or over a lower electrode. In embodiments, a method of manufacturing an image sensor may include treating a first-type conductive layer pattern with plasma. An intrinsic layer may be formed on and/or over an upper dielectric film, and an intrinsic layer may substantially cover a first-type conductive layer pattern in accordance with embodiments. In embodiments, a method of manufacturing an image sensor may include forming a second-type conductive layer on an/or over an intrinsic layer.

Embodiments relate to a method of fabricating an image sensor. According to embodiments, a method of manufacturing an image sensor may include forming a readout circuitry on and/or over a substrate, such as a semiconductor substrate. In embodiments, a method of manufacturing an image sensor may include forming an interlayer dielectric film provided with metal lines on and/or over a semiconductor substrate. In embodiments, a method of manufacturing an image sensor may include forming an upper dielectric film on and/or over an interlayer dielectric film. In embodiments, a method of manufacturing an image sensor may include forming a lower electrode connected to metal lines on and/or over an upper dielectric film.

According to embodiments, a method of manufacturing an image sensor may include forming a first-type conductive layer on and/or over a lower electrode and/or a upper dielectric film. In embodiments, a method of manufacturing an image sensor may include patterning a first-type conductive layer, which may form a first-type conductive layer pattern on and/or over a lower electrode. In embodiments, a method of manufacturing an image sensor may include annealing a first-type conductive layer pattern, which may hydrogenate a first-type conductive layer pattern. In embodiments, a method of manufacturing an image sensor may include forming an intrinsic layer on and/or over an upper dielectric film, which may substantially cover a first-type conductive layer pattern. In embodiments, a method of manufacturing an image sensor may include forming a second-type conductive layer on and/or over an intrinsic layer.

### DRAWINGS

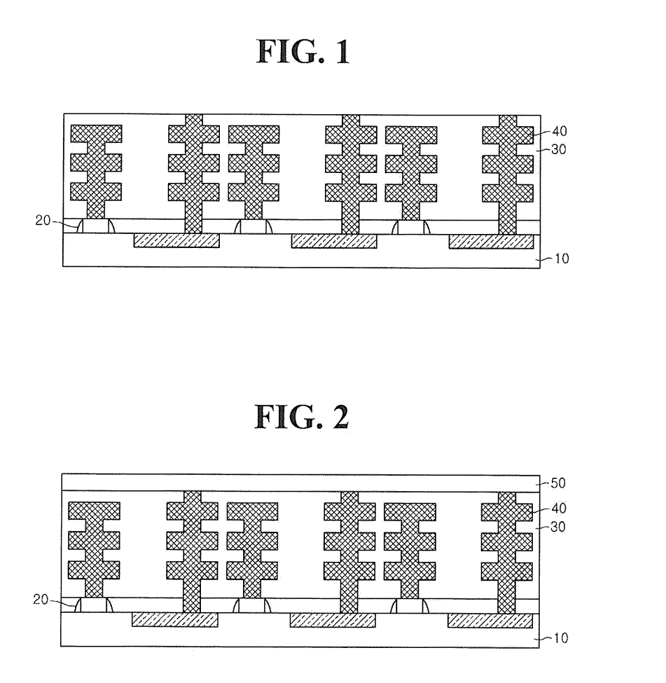

Example FIG. 1 to FIG. 9 illustrate sectional views of a method of fabricating an image sensor in accordance with embodiments.

### DESCRIPTION

Embodiments relate to a method of fabricating an image sensor. Example FIG. 1 to FIG. 9 illustrate sectional views of a method of fabricating an image sensor in accordance with embodiments. Referring to FIG. 1, interlayer dielectric film 30 may include metal lines 40. According to embodiments, interlayer dielectric film 30 may be formed on and/or over a substrate, such as semiconductor substrate 10. In embodiments, semiconductor substrate 10 may be provided with readout circuitry 20.

According to embodiments, readout circuitry 20 may be connected to a photodiode. In embodiments, readout circuitry 20 may be connected to a photodiode to convert received photocharges into electric signals. In embodiments, readout circuitry 20 may be provided in and/or over each pixel unit on and/or over semiconductor substrate 10. In embodiments, readout circuitry 20 may be 3 Tr, 4 Tr and/or 5 Tr. In embodiments, readout circuitry 20 may include a plurality of transistors. In embodiments, transistors may include transfer transistors, reset transistors, drive transistors and/or select transistors. In embodiments, readout circuitry 20 may include a floating diffusion area where impurity ions may be implanted into semiconductor substrate 10 and/or an active region including source/drain regions for respective transistors.

According to embodiments, a pre-metal dielectric (PMD) film may be formed on and/or over semiconductor substrate 10, which may be provided with readout circuitry 20. In embodiments, interlayer dielectric film 30 may be provided with metal lines 40 connected to power and/or signal lines, and may be arranged on and/or over semiconductor substrate 10 provided with readout circuitry 20. In embodiments, interlayer dielectric film 30 may be a multi-layer structure. Interlayer dielectric film 30 may include a nitride film, an oxide film and/or an oxy-nitride film in accordance with embodiments.

According to embodiments, metal lines 40 may serve to transfer electric charges generated in a photodiode to readout circuitry 20. In embodiments, metal lines 40 may be connected to an impurity region, for example arranged under semiconductor substrate 10. In embodiments, metal lines 40 may pass through interlayer dielectric film 30. In embodiments, metal lines 40 may be made of a variety of conductive materials including metals, alloys and/or silicides. Metal lines 40 may be made of aluminum, copper, cobalt and/or tungsten in accordance with embodiments.

Referring to FIG. 2, an upper dielectric film 50 may be arranged on and/or over interlayer dielectric film 30. According to embodiments, upper dielectric film 50 may include at least one of a nitride film, an oxide film and/or an oxy-nitride film. In embodiments, upper dielectric film 50 may be a mono-layer and/or multi-layer structure. In embodiments, upper dielectric film 50 may be a silicon oxide film. Upper dielectric film 50 may be in the form of a multi-layer nitride film/oxynitride film/nitride film structure in accordance with embodiments.

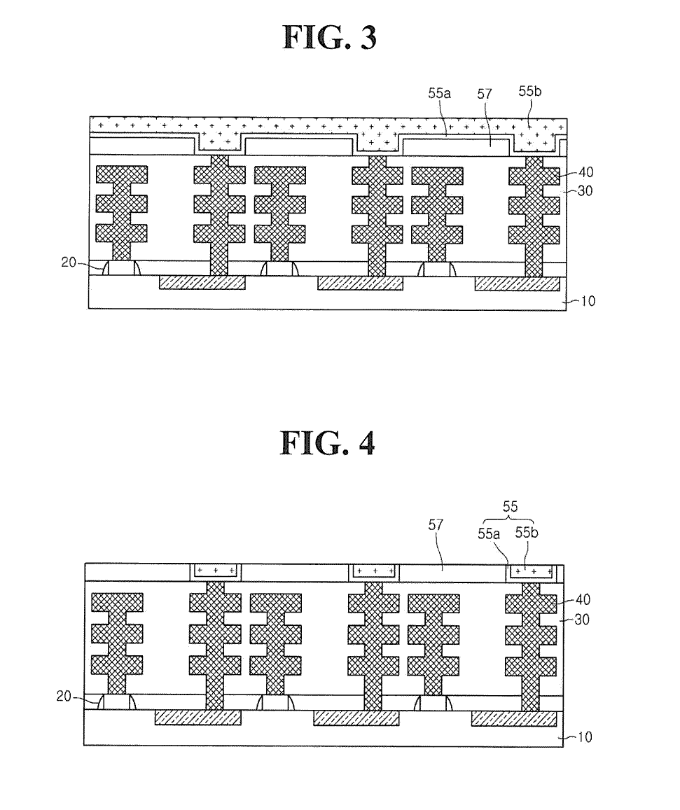

Referring to FIG. 3, upper dielectric film 50 may be patterned. In embodiments, upper dielectric pattern 57 may be formed including a via-hole through which metal lines 40 may be exposed. In embodiments, a photoresist film may be formed on and/or over upper dielectric film 50 and may be selectively exposed to light to form a photoresist pattern. An upper dielectric film may be selectively etched using a photoresist pattern as a mask, and may be removed to form an upper dielectric pattern 57 in accordance with embodiments.

According to embodiments, a barrier film 55a may be deposited on and/or over upper dielectric pattern 57. In embodiments, metal film 55b may be formed on and/or over barrier film 55a. In embodiments, barrier film 55a may be formed on and/or over an upper surface of upper dielectric pattern 57 along an inner side of a via-hole, and may come into contact with metal lines 40 exposed by a via-hole.

According to embodiments, barrier film 55a may include at least one of Ta, TaN, TaAlN, TaSiN, Ti, TiN, WN, TiSiN and/or TCu. In embodiments, barrier film 55a may include a double-layer structure, for example Ti film/TiN film. In embodiments, barrier film 55a may have a thickness between approximately 50 Å to 300 Å. In embodiments, metal film 55b may include at least one of aluminum, titanium, copper, tungsten and/or aluminum alloys. Metal film 55b may be arranged in and/or over a via-hole and may be connected electrically to metal lines 40 through barrier film 55a in accordance with embodiments.

Referring to FIG. 4, metal film 55b may be polished, for example by chemical mechanical polishing (CMP). According to embodiments, a surface of upper dielectric pattern 57 may be exposed. In embodiments, patterns for barrier film 55a and/or metal film 55b may be formed in a via-hole, which may form a lower electrode 55. In embodiments, metal lines 40 may be connected to lower electrode 55, for example by subsequent processes. In embodiments, lower electrode 55 may be provided in each pixel unit. In embodiments, lower electrode 55 may have a thickness between approximately 500 Å to 3,000 Å.

According to embodiments, a surface of lower electrode 55 and/or upper dielectric pattern 57 may be treated with plasma. In embodiments, plasma-treating may maximize adhesion between a photodiode and interlayer dielectric film 30. In embodiments, plasma treatment may include using O₂, H₂, He and/or NH₃, which includes combinations thereof such as H₂/He. In embodiments, plasma treatment may be carried out between approximately 3 minutes to 5 minutes. In embodiments, plasma treatment of an interlayer dielectric film may maximize adhesion strength between, for example, interlayer dielectric film 30 and a film coming into contact with the same.

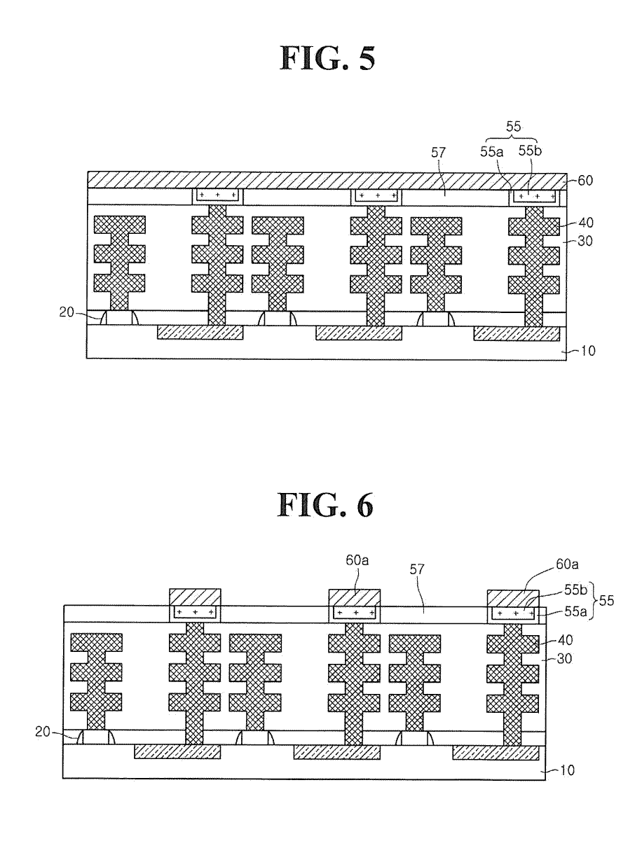

Referring to FIG. 5, an n-type amorphous silicon layer pattern, an intrinsic amorphous silicon layer and/or a p-type amorphous silicon layer may be deposited, for example sequentially, on and/or over lower electrode 55 and/or upper dielectric pattern 57. In embodiments, a photodiode may be formed including an NIP diode. In embodiments, an NIP diode may be a photodiode wherein a pure semiconductor and an intrinsic amorphous silicon layer may be interposed between a p-type silicon layer and a metal. In embodiments, it may be advantageous for generating and/or storing electric charges using an intrinsic amorphous silicon layer interposed therebetween as a depletion region. In embodiments, an n-type amorphous silicon layer arranged on and/or over a interlayer dielectric film may be patterned to form an n-type amorphous silicon layer pattern, and may substantially remove noise generated in pixel units and/or substantially prevent cross-talk.

According to embodiments, an NIP diode may be used as a photodiode and may have a structure of P-I-N, N-I-P, I-P, and/or further like combinations. In embodiments, an N-I-P photodiode may be used. In embodiments, an n-type amorphous silicon layer may be referred to as a first-type conductive layer, such as first-type conductive layer 60. In embodiments, an intrinsic amorphous silicon layer may be referred to as an intrinsic layer, such as intrinsic layer 70. In embodiments, a p-type amorphous silicon layer may be referred to as a second-type conductive layer, such as second-type conductive layer 80.

Embodiments relate to an image sensor including a photodiode, and a method of fabricating a photodiode. According to embodiments, a first-type conductive layer 60 may be formed on and/or over upper dielectric pattern 57 and/or the lower electrode 55. In embodiments, formation of first-type conductive layer 60 may be omitted, and the processes described below may be performed.

According to embodiments, first-type conductive layer 60 may serve as an N-type layer of an N-I-P diode utilized in accordance with embodiments. In embodiments, first-type conductive layer 60 may be an n-type conductive layer and is not limited thereto. In embodiments, first-type conductive layer 60 may be formed by chemical vapor deposition (CVD), for example, plasma enhanced chemical vapor deposition (PECVD). In embodiments, the first-type conductive layer 60 may include n-doped amorphous silicon by depositing a gas mixture of silane (SiH₄) with PH₃ and/or P₂H₅ by PECVD at a temperature between approximately 100° C. to 400° C. First-type conductive layer 60 may have a thickness between approximately 100 Å to 200 Å in accordance with embodiments.

Referring to FIG. 6, first-type conductive layer 60 may be patterned. According to embodiments, first-type conductive layer pattern 60a may be formed on and/or over lower electrode 55. In embodiments, first-type conductive layer pattern 60a may contact lower electrode 55. In embodiments, photoresist patterns may be formed on and/or over first-type conductive layer 60. In embodiments, first-type conductive layer 60 may be etched with plasma using photoresist patterns as masks to form first-type conductive layer patterns 60a. In embodiments, photoresist patterns may be removed. In embodiments, first-type conductive layer patterns 60a may be formed in and/or over respective pixel units and may be separated from each other to prevent cross-talk due to first-type conductive layer patterns. In embodiments, image properties of image sensors may be maximized.

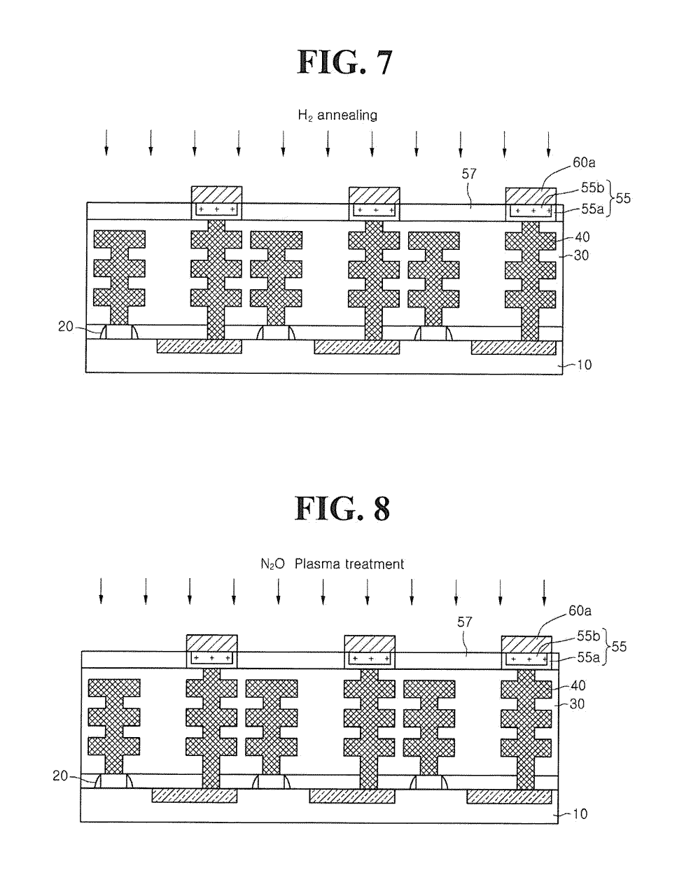

Referring to FIG. 7 and FIG. 8, plasma treatment using N₂O may be performed over a surface, which may be an entire surface, of a substrate provided with first-type conductive layer patterns 60a. In embodiments, plasma treatment using N₂O may be performed to cure damage of first-type conductive layer patterns 60a caused by plasma etching. In embodiments, H₂ annealing may be performed over a surface, which may be an entire surface, of a substrate provided with first-type conductive layer patterns 60a. In embodiments, first-type conductive layer patterns 60a including hydrogenated amorphous silicon (a-Si:H) may be formed. One or both of a N₂O plasma treatment and a H₂ annealing processes may be carried out in accordance with embodiments.

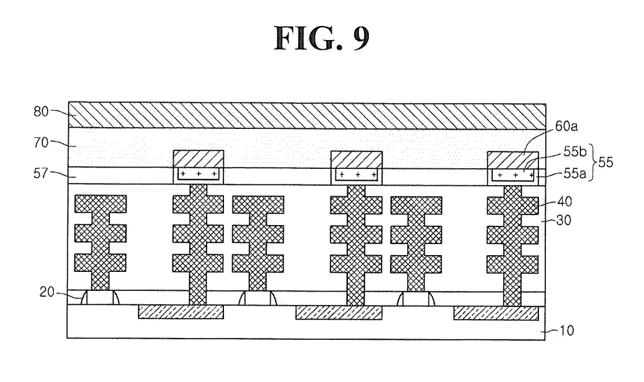

Referring to FIG. 9, intrinsic layer 70 may be formed on and/or over first-type conductive layer pattern 60a. According to embodiments, intrinsic layer 70 may serve as an I-layer of a N-I-P diode utilized in accordance with embodiments. In embodiments, intrinsic layer 70 may be formed using an intrinsic amorphous silicon. In embodiments, intrinsic layer 70 may be formed by chemical vapor deposition (CVD), for example, PECVD. In embodiments, intrinsic layer 70 may include amorphous silicon and may be formed by PECVD using silane gas (SiH₄). In embodiments, intrinsic layer 70 may have a thickness between approximately 2,000 Å to 4,500 Å.

According to embodiments, intrinsic layer 70 may be thicker relative to first-type conductive layer 60. In embodiments, as intrinsic layer 70 becomes relatively thicker, a depletion region of a PIN diode may relatively increase, and may thus be advantageous for storing and/or generating a relatively large amount of photocharges.

According to embodiments, second-type conductive layer 80 may be formed on and/or over intrinsic layer 70. In embodiments, second-type conductive layer 80 and intrinsic layer 70 may be formed by a continuous process. In embodiments, second-type conductive layer 80 may serve as a p-layer of a N-I-P diode utilized in accordance with embodiments. In embodiments, second-type conductive layer 80 may be a p-type conductive layer, but is not limited thereto.

According to embodiments, second-type conductive layer 80 may be formed by chemical vapor deposition (CVD), for example, PECVD. In embodiments, second-type conductive layer 80 may include p-doped amorphous silicon and may be formed by depositing a gas mixture of silane (SiH₄) with PH₃ and/or P₂H₆ by PECVD at a temperate between approximately 100° C. to 400° C. In embodiments, first-type conductive layer 60 may have a thickness between approximately 500 Å to 1,000 Å. In embodiments, first-type conductive layer 60 and/or a first-type conductive layer pattern in each pixel may have a thickness smaller relative to second-type conductive layer 80. In embodiments, second-type conductive layer 80 may have a thickness smaller relative to intrinsic layer 70.

According to embodiments, readout circuitry 20 and a photodiode may be vertically integrated on and/or over semiconductor substrate 10 to yield a fill factor of the photodiode of approximately 100%. In embodiments, an upper electrode may be formed on and/or over semiconductor substrate 10 provided with a photodiode. In embodiments, an upper electrode may include a transparent electrode exhibiting relatively high light transmittance and/or conductivity. In embodiments, an upper electrode may include tin oxide (ITO), cadmium tin oxide (CTO) and/or ZnO, by PVD. In embodiments, an upper electrode may be formed having a thickness between approximately 100 Å to 1,000 Å. In embodiments, upper electrode may be provided with a color filter and/or a microlens thereover.

Embodiments relate to an image sensor. According to embodiments, an n-type amorphous silicon layer may be arranged on and/or over an interlayer dielectric film and may substantially cover a readout circuitry disposed on and/or over a lower substrate. In embodiments, an n-type amorphous silicon layer may be patterned to substantially remove noise in a pixel, to substantially prevent cross talk, and/or maximize image properties.

According to embodiments, an n-type amorphous silicon layer may be patterned and may be treated using N₂O plasma to cure a patterned n-type amorphous silicon layer. In embodiments, defect-causing materials on and/or over an interface may be substantially removed. In embodiments, process stability and/or yield may be maximized.

According to embodiments, an image sensor may substantially prevents deterioration of device properties resulting from oxygen plasma damage generated during etching of, for example, an n-type amorphous silicon layer. In embodiments, transfer efficiency of photocharges may be maximized.

It will be obvious and apparent to those skilled in the art that various modifications and variations can be made in the embodiments disclosed. Thus, it is intended that the disclosed embodiments cover the obvious and apparent modifications and variations, provided that they are within the scope of the appended claims and their equivalents.

What is claimed is:

1. An apparatus comprising:
a readout circuitry over a semiconductor substrate;
an interlayer dielectric film over said semiconductor substrate comprising at least one Metal line;
a lower electrode over said interlayer dielectric film connected to said at least one metal line;
a first-type conductive layer pattern over said lower electrode;
an intrinsic layer over a surface of said semiconductor substrate such that said intrinsic layer substantially covers at least said first-type conductive layer pattern; and
a second-type conductive layer over said intrinsic layer.

2. The apparatus of claim 1, comprising an upper transparent electrode over said second-type conductive layer.

3. The apparatus of claim 1, wherein said first-type conductive layer pattern comprises n-type amorphous silicon.

4. The apparatus of claim 1, wherein said second-type conductive layer comprises p-type amorphous silicon.

5. The apparatus of claim 1, wherein said intrinsic layer comprises amorphous silicon.

6. The apparatus of claim 1, wherein said first-type conductive layer pattern comprises a smaller thickness relative to said second-type conductive layer and said second-type conductive layer comprises a smaller thickness relative to said intrinsic layer.

7. The apparatus of claim 6, wherein the thickness of said intrinsic layer is between approximately 2,000 Å to 4,500 Å.

8. The apparatus of claim 1, wherein said lower electrode comprises at least one of a barrier film and a metal film.

9. A method comprising:
forming a readout circuitry over a semiconductor substrate;
forming an interlayer dielectric film comprising at least one metal line over said semiconductor substrate;
forming an upper dielectric film over said interlayer dielectric film;
forming a lower electrode over said upper dielectric film connected to said at least one metal line;
forming a first-type conductive layer over at least a portion of said lower electrode and said upper dielectric film;
patterning said first-type conductive layer to form a first-type conductive layer pattern over said lower electrode;
plasma-treating said first-type conductive layer pattern;
forming an intrinsic layer over at least a portion of said upper dielectric film such that said intrinsic layer substantially covers said first-type conductive layer pattern; and
forming a second-type conductive layer over said intrinsic layer.

10. The method of claim 9, wherein plasma-treating comprises using N₂O.

11. The method of claim 9, comprising:
H₂-annealing said first-type conductive layer pattern after said plasma-treating; and
hydrogenating said first-type conductive layer pattern.

12. The method of claim 9, comprising plasma-treating said lower electrode and said upper dielectric film comprising using at least one of O₂, H₂, He and NH₃.

13. The method of claim 9, wherein said first-type conductive layer pattern comprises n-type amorphous silicon, said second-type conductive layer comprises p-type amorphous silicon and said intrinsic layer comprises amorphous silicon.

14. The method of claim 9, wherein forming said lower electrode comprises:
patterning said upper dielectric film to form a via-hole exposing said at least one metal line;
depositing a barrier film and a metal film over said upper dielectric film comprising the via-hole; and
polishing said metal film and said barrier film to form said lower electrode connected to said at least one metal line in the via-hole.

15. A method comprising:
forming a readout circuitry over a semiconductor substrate;
forming an interlayer dielectric film comprising at least one metal line over said semiconductor substrate;
forming an upper dielectric film over said interlayer dielectric film;
forming a lower electrode over said upper dielectric film connected to said at least one metal line;
forming a first-type conductive layer over at least a portion of said lower electrode and said upper dielectric film;
patterning said first-type conductive layer to form a first-type conductive layer pattern over said lower electrode;
annealing said first-type conductive layer pattern to hydrogenate said first-type conductive layer pattern;
forming an intrinsic layer over said upper dielectric film such that said intrinsic layer substantially covers said first-type conductive layer pattern; and
forming a second-type conductive layer over said intrinsic layer.

16. The method of claim 15, wherein said annealing comprises using hydrogen annealing.

17. The method of claim 15, comprising plasma-treating said first-type conductive layer pattern comprising using N₂O before said annealing.

18. The method of claim 15, comprising plasma-treating said lower electrode and said upper dielectric film comprising using at least one of O₂, H₂, He and NH₃.

19. The method of claim 15, wherein said first-type conductive layer pattern comprises n-type amorphous silicon, said second-type conductive layer comprises p-type amorphous silicon and said intrinsic layer comprises amorphous silicon.

20. The method of claim 15, wherein forming said lower electrode comprises:
patterning said upper dielectric film to form a via-hole exposing said at least one metal line;
depositing a barrier film and a metal film over said upper dielectric film comprising the via-hole; and
polishing said metal film and said barrier film to form said lower electrode connected to said at least one metal line in the via-hole.
